(19) United States
(12) Patent Application Publication
(10) Pub. No.: US 2026/0190409 A1
(43) Pub. Date: Jul. 2, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Ya-Ling LEE, Hsinchu (TW); Ming-Wei LAI, Hsinchu (TW); I-Cheng CHANG, Hsinchu (TW); Chao-Cheng CHEN, Hsinchu (TW); Yu-Jen CHIEN, Hsinchu (TW)

(73) Assignee: Taiwan Semiconductor Manufacturing Company, Ltd., Hsinchu (TW)

(21) Appl. No.: 19/003,468

(22) Filed: Dec. 27, 2024

(51) Int. Cl. H10D 62/17; H10D 30/01; H10D 30/63; H10D 62/60; H10D 62/80; H10D 64/27

(52) U.S. Cl. CPC H10D 62/235; H10D 30/027; H10D 30/637; H10D 62/60; H10D 62/875; H10D 64/514

(57) ABSTRACT

A semiconductor device includes a substrate and a transistor. The transistor is disposed on the substrate and includes a gate, an active channel layer and an insulation layer. The gate is disposed on the substrate. The active channel layer is disposed above the gate. The insulation layer is disposed between the gate and the active channel layer. The active channel layer includes an upper portion and a lower portion, and the upper portion has a doping concentration greater than that of the lower portion.

### BACKGROUND

Al—O (aluminium-oxide) bonding is more stable than In—O and Zn—O, could improve stability. However, the Al need to be controlled in low dosing (<3 atm %) to avoid reduction of carrier concentration and mobility. It is hard to control Al content in traditional deposition process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a cross-sectional view of a semiconductor device according to an embodiment of the present disclosure;

FIG. 1B illustrates a schematic diagram of a relationship curve of a doping concentration and a position of the active channel layer of the semiconductor device in FIG. 1A;

FIGS. 2A to 2H illustrate schematic diagrams of manufacturing processes of the semiconductor device in FIG. 1A; and

FIG. 3 illustrates a flow chat of manufacturing processes of an active channel layer in FIG. 2C.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

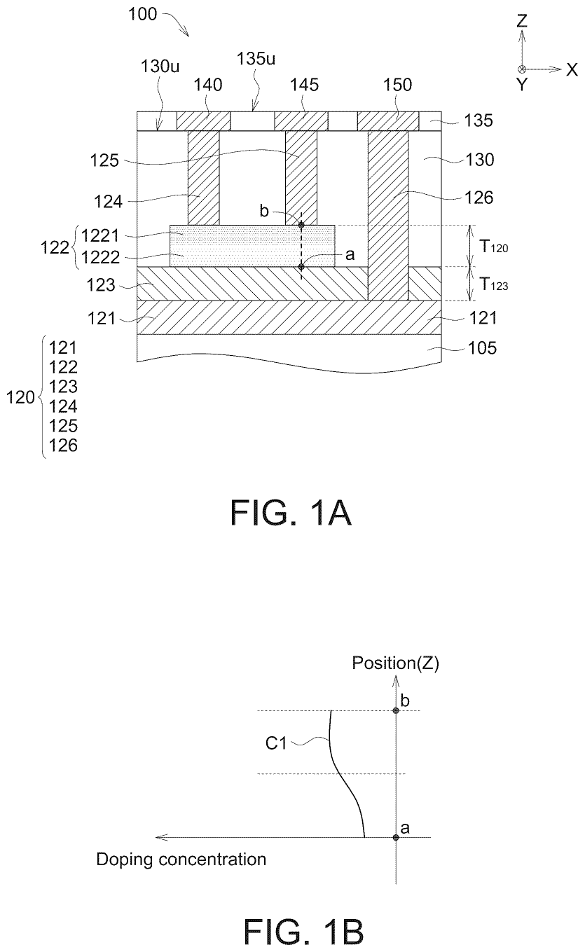

Referring to FIGS. 1A and 1B, FIG. 1A illustrates a schematic diagram of a cross-sectional view of a semiconductor device 100 according to an embodiment of the present disclosure, and FIG. 1B illustrates a schematic diagram of a relationship curve of a doping concentration and a position of the active channel layer 122 of the semiconductor device 100 in FIG. 1A.

As illustrated in FIG. 1A, the semiconductor device 100 includes a substrate 110, a transistor 120, a dielectric layer 130 and 135, a first conductive pad 140, a second conductive pad 145 and a gate conductive pad 150. The transistor 120 is disposed on the substrate 110 and includes a gate 121, an active channel layer 122, an insulation layer 123, a first conductive via 124, a second conductive via 125 and a gate via 126. The active channel layer 122 is disposed above or on the gate 121. The insulation layer 123 is disposed between the gate 121 and the active channel layer 122. The active channel layer 122 includes an upper portion 1221 and a lower portion 1222, and the upper portion 1221 has a doping concentration (as illustrated in a curve C1 in FIG. 1B) greater than that of the lower portion 1222. In the present embodiment, the dopants in the active channel layer 122 are non-uniformly distributed in the active channel layer 122 due to the manufacturing processes for the active channel layer 122 of the semiconductor device 100.

In the present embodiment, the dopants (for example, aluminium oxide) may be accurately controlled in low dosing (for example, <3 atm %) to avoid reduction of carrier concentration and mobility, and obtain a reliability improvement and a tunable driving voltage for the gate (for example, the higher the concentration of the aluminium oxide is, the higher the positive driving bias is).

In addition, a cross-section in any position of the active channel layer 122 along X-axis has the doping concentration the same as or similar to the doping concentration as illustrated in the curve C1 of FIG. 1B.

As illustrated in FIG. 1A, the substrate 110 may include a base (for example, portion of a silicon wafer), a FEOL (front-end-of-line) structure and a BEOL (back end of line) structure, wherein the FEOL structure is disposed on the base, and the BEOL structure is disposed on the FEOL structure. In the present embodiment, the transistor 120 may be formed in or on the BEOL structure, or in or on the FEOL structure.

As illustrated in FIG. 1A, the gate 121 is, for example, metal gate. The metal gate may be formed of a material including, for example, Ti, TiN, Ta, TaN, Al, Cu, Co, Ru, W, Au or a combination thereof.

As illustrated in FIG. 1A, the active channel layer 122 may be formed of, for example, IGZO (indium gallium zinc oxide) in which aluminium oxide (for example, Al₂O₃) is doped. The active channel layer 120 has a thickness T₁₂₀ may range between, for example, 40 Ångstrom (Å) and 500 Å, or even greater or less.

As illustrated in FIG. 1A, the insulation layer 123 may be formed of an insulation material, for example, oxide, etc. The insulation layer 123 has a thickness T₁₂₃ may range between, for example, 20 Å and 100 Å, or even greater or less. In addition, the insulation layer 123 may be formed of a material including, for example, SiO₂, Al₂O₃, HfO₂, etc.

As illustrated in FIG. 1A, the first conductive via 124 is formed within the dielectric layer 130, and extends to the active channel layer 122 from an upper surface 130u of the dielectric layer 130. The first conductive via 124 is, for example, one of a source via and a drain via of the transistor 120. The first conductive via 124 may be formed of a material including, for example, Ti, TiN, Ta, TaN, Al, Cu, Co, Ru, W, Au or a combination thereof.

As illustrated in FIG. 1A, the second conductive via 125 is formed within the dielectric layer 130, and extends to the active channel layer 122 from the upper surface 130u of the dielectric layer 130. The second conductive via 125 is, for example, another of the source via and the drain via of the transistor 120. The second conductive via 125 may be formed of a material including, for example, Ti, TiN, Ta, TaN, Al, Cu, Co, Ru, W, Au or a combination thereof.

As illustrated in FIG. 1A, the gate via 126 is formed within the dielectric layer 130, and extends to the active channel layer 122 from the upper surface 130u of the dielectric layer 130. The gate via 126 is, for example, another of the source via and the drain via of the transistor 120. The second conductive via 125 may be formed of a material including, for example, Ti, TiN, Ta, TaN, Al, Cu, Co, Ru, W, Au or a combination thereof.

As illustrated in FIG. 1A, the dielectric layer 135 is disposed over the dielectric layer 130. The first conductive pad 140 is disposed in the dielectric layer 135 and extends to the first conductive via 124 from an upper surface 135u of the dielectric layer 135. The second conductive pad 145 is disposed in the dielectric layer 135 and extends to the second conductive via 125 from the upper surface 135u of the dielectric layer 135. The gate conductive pad 150 is disposed in the dielectric layer 135 and extends to the gate 121 from the upper surface 135u of the dielectric layer 135.

In another embodiment, the semiconductor device 100 further includes at least one dielectric layer disposed between the dielectric layer 135 and the dielectric layer 130, and further includes at least one conductive portion (via and/or trace) disposed in the dielectric layer between the dielectric layer 135 and the dielectric layer 130. The conductive portion in one of the dielectric layers may electrically connect the conductive portions in two of the dielectric layers respectively.

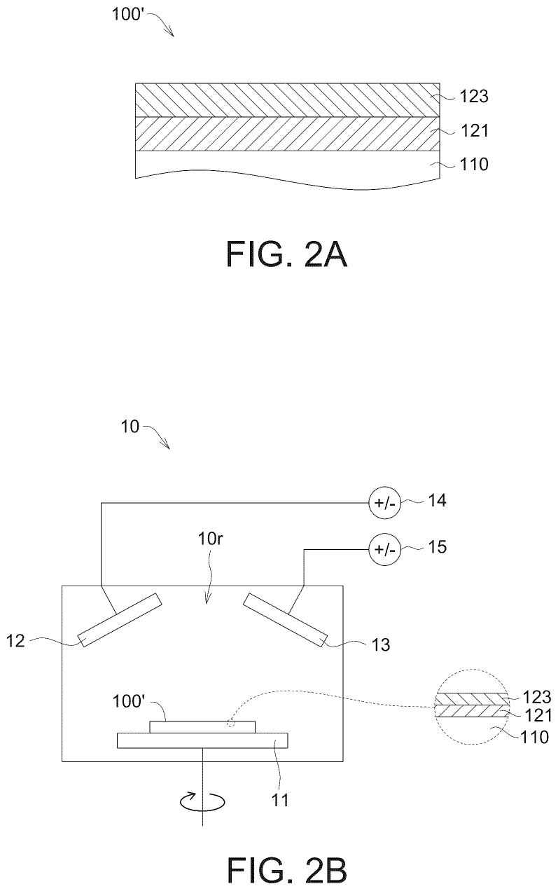

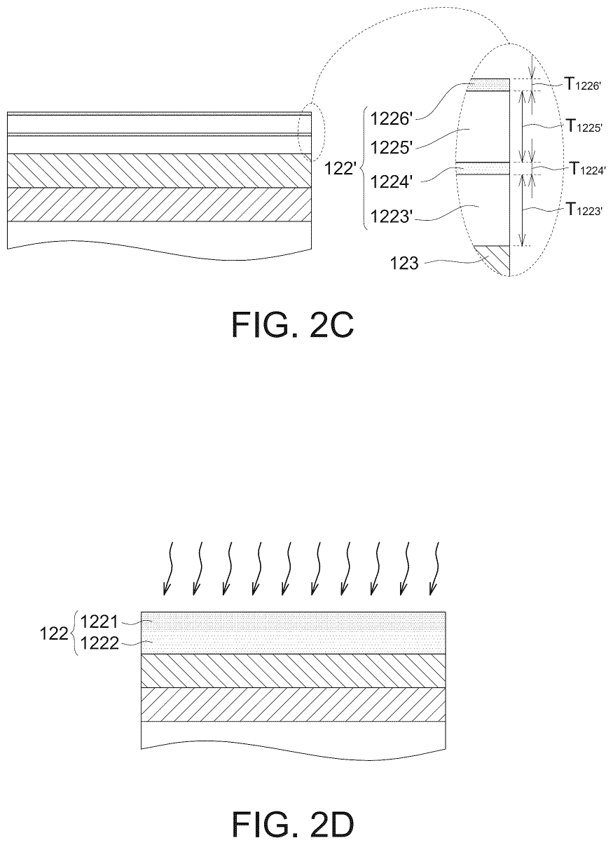

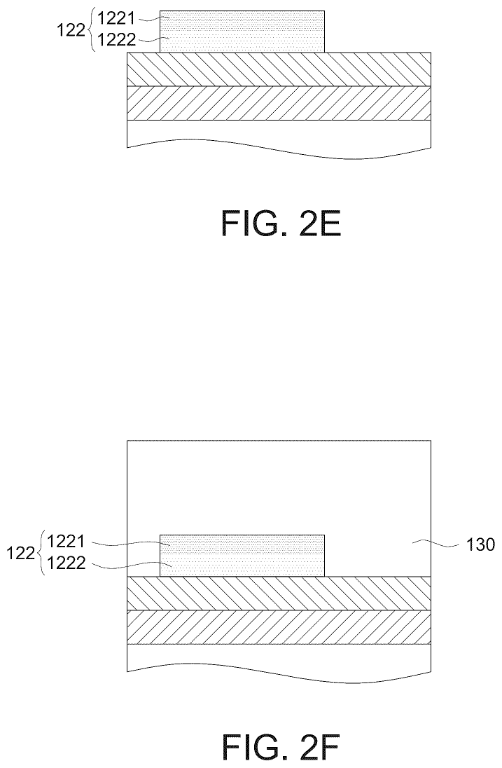

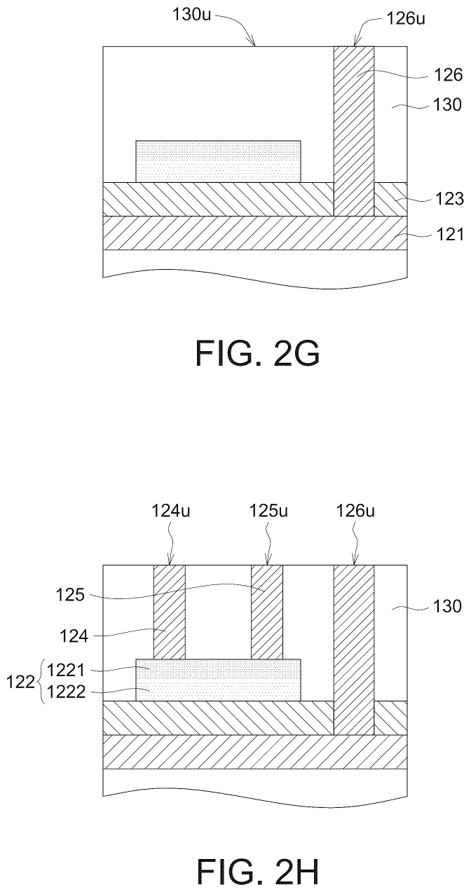

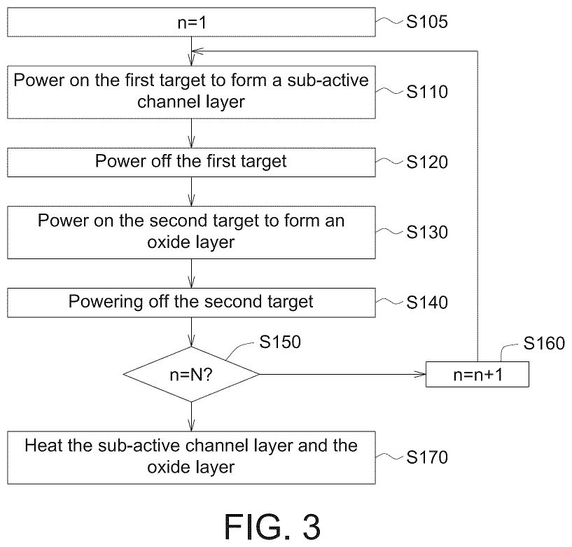

Referring FIGS. 2A to 2H and 3, FIGS. 2A to 2H illustrate schematic diagrams of manufacturing processes of the semiconductor device 100 in FIG. 1A, and FIG. 3 illustrates a flow chat of manufacturing processes of an active channel layer 122′ in FIG. 2C.

As illustrated in FIG. 2A, the gate layer 121′ is formed on the substrate 110 by using, for example, deposition. Then, the insulation layer 123′ is formed on the gate layer 121′ by using, for example, deposition. The insulation layer 123′ may be formed of a material including SiO₂, Al₂O₃, HfO₂, etc.

As illustrated in FIG. 2B, a deposition apparatus 10 is provided. The deposition apparatus 10 is, for example, PVD (Physical vapor deposition) apparatus. The deposition apparatus 10 has a chamber 10r and includes a platform (or a stage) 11, a first target 12, a second target 13, a first power 14 and a second power 15, wherein the platform 11, the first target 12 and the second target 13 are disposed in the chamber 10r. The first power 14 is electrically connected with the first target 12 for powering on the first target 12, and the second power 15 is electrically connected with the second target 13 for powering on the second target 13.

As illustrated in FIG. 2B, the structure 100′ in FIG. 2A is transferred to the chamber 10r of the deposition apparatus 10, and is placed on the platform 11 of the deposition apparatus 10.

As illustrated in FIG. 2C, the steps S110 to S140 in FIG. 3 may be performed at least once form an active channel layer 122′ on the insulation layer 123.

In step S105 of FIG. 3, the initial value of “n” may be set as 1 by a controller (not illustrated). The controller may be electrically connected with the first power 14, the second power 15 for controlling these powers.

In step S110 of FIG. 3, as illustrated in FIG. 2C, the first power 14 may power on the first target 12 to form a sub-active channel layer. Furthermore, proper Ar/O₂ flows to the chamber 10r of the deposition apparatus 10, and the first power 14 may power on the first target 12 to form a first sub-active channel layer 1223′ on the insulation layer 123 by PVD. The first sub-active channel layer 1223′ may be formed of, for example, IGZO.

In step S120 of FIG. 3, the first power 14 may power off the first target 12 when the first sub-active channel layer 1223′ with a thickness T_{1223′} is formed. In an embodiment, the thickness T_{1223′} may account for, for example, 50 % of the thickness T₁₂₀ of the active channel layer 120 in FIG. 1A. In an embodiment, the thickness T₁₂₂₃′ of the first sub-active channel layer 1223′ may range between, for example, 20 Å and 250 Å.

In step S130 of FIG. 3, as illustrated in FIG. 2C, the second power 15 may power on the second target 13 to form an oxide layer. Furthermore, proper Ar/O₂ flows to the chamber 10r of the deposition apparatus 10, and the second power 15 may power on the second target 13 to form a first oxide layer 1224′ on the first sub-active channel layer 1223′ by PVD. The first oxide layer 1224′ may be formed of, for example, aluminium oxide (Al₂O₃). A thickness T_{1224′} of the first oxide layer 1224′ may be decided by evaporation time. In an embodiment, when the evaporation time lasts 3 seconds, the second sub-active channel layer 1224′ may be formed to the thickness T_{1224′} of, for example, 1 Å to 3 Å.

In step S140 of FIG. 3, as illustrated in FIG. 2C, the second power 15 may power off the second target 13 when the first oxide layer 1224′ with the thickness T_{1224′} of, for example, 1 Å to 3 Å is formed.

In step S150 of FIG. 3, whether n is equal to N is determined. If n is not equal to N, the process proceeds to step S160. If n is equal to N, the process proceeds to step S170. In addition, N may be a positive integer equal to or greater than 1. The value of N may be decided according to the required thickness T₁₂₀ of the active channel layer 120 or the oxide concentration of the active channel layer 120 in FIG. 1A. In the present embodiment, the value of N is equal to 2.

In step S160 of FIG. 3, the value of n is accumulated, for example, n=n+1. Then, as illustrated in FIG. 2C, the process returns to step S110 to form a second sub-active channel layer 1225′ on the second oxide layer 1224′ (for example, in step S110), and form a second oxide layer 1226′ (for example, in step S130) on the second sub-active channel layer 1225′. The first sub-active channel layer 1223′, the first oxide layer 1224′, the second sub-active channel layer 1225′ and the second oxide layer 1226′ form the active channel layer 122′.

In an embodiment, the second sub-active channel layer 1225′ may be formed of a material the same as or similar to that of the first sub-active channel layer 1223′. A thickness T_{1225′} of the second sub-active channel layer 1225′ may account for, for example, 50 % of the thickness T₁₂₀ of the active channel layer 120 in FIG. 1A. The thickness T_{1225′} of the second sub-active channel layer 1225′ may range between, for example, 20 Å and 250 Å. The second oxide layer 1226′ may be formed of a material the same as or similar to that of the first oxide layer 1224′. The second oxide layer 1226′ may be formed to a thickness T_{1226′} of, for example, 1 Å to 3 Å.

In step S170 of FIG. 3, as illustrated in FIG. 2D, the active channel layer 122′ including the first sub-active channel layer 1223′, the first oxide layer 1224′, the second sub-active channel layer 1225′ and the second oxide layer 1226′ is heated at a temperature ranging between, for example, 200 degrees Celsius and 400 degrees Celsius. The heating process may provide a more stable film and tunable voltage for the gate.

As illustrated in FIG. 2D, in heating process, the aluminium oxide in the first oxide layer 1224′ and the second oxide layer 1226′ may diffuse into the first sub-active channel layer 1223′ and the second sub-active channel layer 1225′. After diffusing, there is no obvious interface between adjacent two active channel layers. After heating, the active channel layer 122′ forms the active channel layer 122 in FIG. 1A and has the distribution of the doping concentration as illustrated in FIG. 1B.

As illustrated in FIG. 2E, the active channel layer 122 in FIG. 2D is patterned by using, for example, deposition, lithography, etching, etc.

As illustrated in FIG. 2F, the dielectric layer 130 covering the active channel layer 122 in FIG. 2E is formed by using, for example, deposition, etc.

As illustrated in FIG. 2G, the gate via 126 passing through the dielectric layer 130 and the insulation layer 123 to connect with the gate 121 is formed by using, for example, deposition, lithography, etching, CMP, etc. After CMP, the gate via 126 forms an upper surface 126u, the dielectric layer 130 forms the upper surface 130u, and the upper surface 126u and the upper surface 130u are aligned with (for example, flushed with) each other.

As illustrated in FIG. 2H, the first conductive via 124 passing through the dielectric layer 130 to connect with the active channel layer 122 is formed by using, for example, deposition, lithography, etching, CMP, etc. The second conductive via 125 passing through the dielectric layer 130 to connect with the active channel layer 122 is formed by using, for example, deposition, lithography, etching, CMP, etc. After CMP, the first conductive via 124 forms an upper surface 124u, the second conductive via 125 forms an upper surface 125u, and the upper surface 124u, the upper surface 125u and the upper surface 130u are aligned with (for example, flushed with) each other.

In another embodiment, the gate via 126, the first conductive via 124 and the second conductive via 125 may be formed at the same process.

Then, the dielectric layer 135 in FIG. 1A over the dielectric layer 130 is formed by using, for example, deposition, etc. Then, the first conductive pad 140, the second conductive pad 145 and the gate conductive pad 150 in FIG. 1A passing through the dielectric layer 135 are formed by using, for example, deposition, lithography, etching, etc. The first conductive pad 140 is connected with the first conductive via 124, the second conductive pad 145 is connected with the second conductive via 125, and the gate conductive pad 150 is connected with the gate via 126. So far, the semiconductor device 100 as illustrated in FIG. 1A may the formed.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a transistor at least including an active channel layer, wherein the active channel layer includes a plurality of portion which have different doping concentration.

Example embodiment 1: a semiconductor device includes a substrate and a transistor. The transistor is disposed on the substrate and includes a gate, an active channel layer and an insulation layer. The gate is disposed on the substrate. The active channel layer is disposed above the gate. The insulation layer is disposed between the gate and the active channel layer. The active channel layer includes an upper portion and a lower portion, and the upper portion has a doping concentration greater than that of the lower portion.

Example embodiment 2 based on Example embodiment 1: the active channel layer is formed of IGZO (indium gallium zinc oxide) in which aluminium oxide is doped.

Example embodiment 3 based on Example embodiment 1: the active channel layer has a thickness ranging 40 Ångstrom (Å) and 500 Å.

Example embodiment 4 based on Example embodiment 1: the insulation layer has a thickness ranging 20 Å and 100 Å.

Example embodiment 5: a semiconductor device includes a substrate and a transistor. The transistor is disposed on the substrate and includes a gate, an active channel layer and an insulation layer. The gate is disposed on the substrate. The active channel layer is disposed above the gate. The active channel layer includes a first portion and a second portion, and the first portion has a doping concentration different from that of the second portion.

Example embodiment 6 based on Example embodiment 5: the active channel layer is formed of IGZO (indium gallium zinc oxide) in which aluminium oxide is doped.

Example embodiment 7 based on Example embodiment 5: the active channel layer has a thickness ranging 40 Å and 500 Å.

Example embodiment 8 based on Example embodiment 5: the insulation layer has a thickness ranging 20 Å and 100 Å.

Example embodiment 9: a manufacturing method for a semiconductor device includes the following steps: providing a substrate; and forming a transistor, including: forming a gate on the substrate; forming an insulation layer on the gate; and forming an active channel layer on the insulation layer. The active channel layer includes an upper portion and a lower portion, and the upper portion has a doping concentration greater than that of the lower portion.

Example embodiment 10 based on Example embodiment 9: forming the active channel layer on the gate includes: forming a first sub-active channel layer on the insulation layer; and forming a first oxide layer on the first sub-active channel layer.

Example embodiment 11 based on Example embodiment 10: first sub-active channel layer ranges between 20 Å and 250 Å, and the first oxide layer ranges between 1 Å and 3 Å.

Example embodiment 12 based on Example embodiment 10: the first sub-active channel layer is formed of IGZO, and the first oxide layer is formed of aluminium oxide.

Example embodiment 13 based on Example embodiment 10: the semiconductor method further includes: transferring the substrate to a chamber of a deposition apparatus; forming the first sub-active channel layer on the insulation layer in the deposition apparatus; and forming the first oxide layer on the first sub-active channel layer in the deposition apparatus.

Example embodiment 14 based on Example embodiment 13: the deposition apparatus includes a first target and a second target; the semiconductor method further includes: powering on the first target to form the first sub-active channel layer on the insulation layer; powering off the first target; powering on the second target to form the first oxide layer on the first sub-active channel layer; and powering off the second target.

Example embodiment 15 based on Example embodiment 10: forming the active channel layer on the insulation layer includes: forming a second sub-active channel layer on the first oxide layer; and forming a second oxide layer on the second sub-active channel layer.

Example embodiment 16 based on Example embodiment 15: the second sub-active channel layer is formed of IGZO, and the second oxide layer is formed of aluminium oxide.

Example embodiment 17 based on Example embodiment 15: forming the active channel layer on the insulation layer includes: heating the first sub-active channel layer, the first oxide layer, the second sub-active channel layer and the second oxide layer.

Example embodiment 18 based on Example embodiment 17: forming the active channel layer on the insulation layer includes: heating the first sub-active channel layer, the first oxide layer, the second sub-active channel layer and the second oxide layer at a temperature higher than 200 degrees Celsius.

Example embodiment 19 based on Example embodiment 15: the semiconductor method further includes: forming the second sub-active channel layer on the second sub-active channel layer in the deposition apparatus; and forming the second oxide layer on the second sub-active channel layer in the same deposition apparatus.

Example embodiment 20 based on Example embodiment 19: the deposition apparatus includes a first target and a second target; the semiconductor method further includes: powering on the first target for forming the second sub-active channel layer on the first oxide layer; powering off the first target; powering on the second target for forming the second oxide layer on the second sub-active channel layer; and powering off the second target.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
a transistor on the substrate, comprising:
a gate on the substrate;
an active channel layer above the gate; and
an insulation layer between the gate and the active channel layer;
wherein the active channel layer comprising an upper portion and a lower portion, and the upper portion has a doping concentration greater than that of the lower portion.

2. The semiconductor device as claimed in claim 1, wherein the active channel layer formed of IGZO (indium gallium zinc oxide) in which aluminium oxide is doped.

3. The semiconductor device as claimed in claim 1, wherein the active channel layer has a thickness ranging 40 Ångstrom (Å) and 500 Å.

4. The semiconductor device as claimed in claim 1, wherein the insulation layer has a thickness ranging 20 Å and 100 Å.

5. A semiconductor device, comprising:
a substrate; and
a transistor on the substrate, comprising:
a gate on the substrate;
an active channel layer above the gate; and
an insulation layer between the gate and the active channel layer;
wherein the active channel layer comprising a first portion and a second portion, and the first portion has a doping concentration different from that of the second portion.

6. The semiconductor device as claimed in claim 5, wherein the active channel layer formed of IGZO (indium gallium zinc oxide) in which aluminium oxide is doped.

7. The semiconductor device as claimed in claim 5, wherein the active channel layer has a thickness ranging 40 Å and 500 Å.

8. The semiconductor device as claimed in claim 5, wherein the insulation layer has a thickness ranging 20 Å and 100 Å.

9. A manufacturing method for a semiconductor device, comprising:
providing a substrate; and
forming a transistor, comprising:
forming a gate on the substrate;
forming an insulation layer on the gate; and
forming an active channel layer on the insulation layer;
wherein the active channel layer comprising an upper portion and a lower portion, and the upper portion has a doping concentration greater than that of the lower portion.

10. The manufacturing method as claimed in claim 9, wherein forming the active channel layer on the gate comprises:
forming a first sub-active channel layer on the insulation layer; and
forming a first oxide layer on the first sub-active channel layer.

11. The manufacturing method as claimed in claim 10, wherein first sub-active channel layer ranges between 20 Å and 250 Å, and the first oxide layer ranges between 1 Å and 3 Å.

12. The semiconductor method as claimed in claim 10, wherein the first sub-active channel layer is formed of IGZO, and the first oxide layer is formed of aluminium oxide.

13. The semiconductor method as claimed in claim 10, further comprising:
transferring the substrate to a chamber of a deposition apparatus;
forming the first sub-active channel layer on the insulation layer in the deposition apparatus; and
forming the first oxide layer on the first sub-active channel layer in the deposition apparatus.

14. The semiconductor method as claimed in claim 13, wherein the deposition apparatus comprises a first target and a second target; the semiconductor method further comprises:
powering on the first target to form the first sub-active channel layer on the insulation layer;
powering off the first target;
powering on the second target to form the first oxide layer on the first sub-active channel layer; and
powering off the second target.

15. The manufacturing method as claimed in claim 10, wherein forming the active channel layer on the insulation layer comprises:
forming a second sub-active channel layer on the first oxide layer; and
forming a second oxide layer on the second sub-active channel layer.

16. The semiconductor method as claimed in claim 15, wherein the second sub-active channel layer is formed of IGZO, and the second oxide layer is formed of aluminium oxide.

17. The manufacturing method as claimed in claim 15, wherein forming the active channel layer on the insulation layer comprises:
heating the first sub-active channel layer, the first oxide layer, the second sub-active channel layer and the second oxide layer.

18. The manufacturing method as claimed in claim 17, wherein forming the active channel layer on the insulation layer comprises:
heating the first sub-active channel layer, the first oxide layer, the second sub-active channel layer and the second oxide layer at a temperature higher than 200 degrees Celsius.

19. The semiconductor method as claimed in claim 15, further comprising:
forming the second sub-active channel layer on the second sub-active channel layer in the deposition apparatus; and
forming the second oxide layer on the second sub-active channel layer in the same deposition apparatus.

20. The semiconductor method as claimed in claim 19, wherein the deposition apparatus comprises a first target and a second target; the semiconductor method further comprises:
powering on the first target for forming the second sub-active channel layer on the first oxide layer;
powering off the first target;
powering on the second target for forming the second oxide layer on the second sub-active channel layer; and
powering off the second target.
